(19) United States
(12) Patent Application Publication
(10) Pub. No.: US 2026/0163549 A1
(43) Pub. Date: Jun. 11, 2026

(54) MULTILAYER PIEZOELECTRIC SUBSTRATE SURFACE ACOUSTIC WAVE DEVICE WITH MULTILAYER INTERDIGITAL TRANSDUCER ELECTRODE

(71) Applicant: Skyworks Solutions, Inc., Irvine, CA (US)

(72) Inventor: Rei Goto, Osaka-Shi (JP)

(21) Appl. No.: 19/390,267

(22) Filed: Nov. 14, 2025

Related U.S. Application Data
(60) Provisional application No. 63/730,244, filed on Dec. 10, 2024.
(60) Provisional application No. 63/730,180, filed on Dec. 10, 2024.

(51) Int. Cl. H03H 9/02; H03H 9/145; H03H 9/25; H03H 9/64

(52) U.S. Cl. CPC H03H 9/02897; H03H 9/14538; H03H 9/25; H03H 9/6483

(57) ABSTRACT

A surface acoustic wave device is disclosed. The surface acoustic wave device can include a piezoelectric layer and a multi-layer interdigital transducer electrode in electrical communication with the piezoelectric layer. The multi-layer interdigital transducer electrode includes a first layer, a second layer, and a third layer between the first layer and the second layer. A first mass density of the first layer can be greater than a second mass density of the second layer, and a third density of the third layer can be greater than the second mass density. The second layer can be more flexible than the first and second layers, and the third layer can be more flexible than the first layer.

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/730,244, filed Dec. 10, 2024, titled “MULTILAYER PIEZOELECTRIC SUBSTRATE SURFACE ACOUSTIC WAVE DEVICE WITH MULTILAYER INTERDIGITAL TRANSDUCER ELECTRODE,” and U.S. Provisional Patent Application No. 63/730,180, filed Dec. 10, 2024, titled “SURFACE ACOUSTIC WAVE DEVICE HAVING MULTILAYER INTERDIGITAL TRANSDUCER ELECTRODE,” are hereby incorporated by reference under 37 CFR 1.57 in their entirety.

### BACKGROUND

### Field

Embodiments of this disclosure relate to multilayer piezoelectric substrate surface acoustic wave (MPS SAW) devices.

### Description of Related Technology

Acoustic wave filters can be implemented in radio frequency electronic systems. For instance, filters in a radio frequency front end of a mobile phone can include acoustic wave filters. An acoustic wave filter can filter a radio frequency signal. An acoustic wave filter can be a band pass filter. A plurality of acoustic wave filters can be arranged as a multiplexer. For example, two acoustic wave filters can be arranged as a duplexer.

An acoustic wave filter can include a plurality of resonators arranged to filter a radio frequency signal. Example acoustic wave filters include surface acoustic wave (SAW) filters and bulk acoustic wave (BAW) filters. A surface acoustic wave resonator can include an interdigital transducer electrode on a piezoelectric substrate. The surface acoustic wave resonator can generate a surface acoustic wave on a surface of the piezoelectric layer on which the interdigital transducer electrode is disposed.

There can be unwanted responses generated in a SAW device, including nonlinearity, which distorts the signal by producing harmonics, intermodulation products, and spurious signals not present in the original input. These effects degrade device performance by reducing signal fidelity and creating interference. In high-precision applications like telecommunications and signal processing, minimizing nonlinearity is crucial to maintain optimal performance, making it a key design goal for SAW devices.

### SUMMARY

The innovations described in the claims each have several aspects, no single one of which is solely responsible for its desirable attributes. Without limiting the scope of the claims, some prominent features of this disclosure will now be briefly described.

In some aspects, the techniques described herein relate to a surface acoustic wave device including: a piezoelectric layer; and a multi-layer interdigital transducer electrode in electrical communication with the piezoelectric layer, the multi-layer interdigital transducer electrode including a first layer, a second layer, and a third layer between the first layer and the second layer, a first mass density of the first layer being greater than a second mass density of the second layer, and the third layer having a third density that is greater than the second mass density.

In some embodiments, the techniques described herein relate to a surface acoustic wave device wherein the first layer includes molybdenum, tungsten, platinum, or ruthenium.

In some embodiments, the techniques described herein relate to a surface acoustic wave device wherein the second layer includes aluminum.

In some embodiments, the techniques described herein relate to a surface acoustic wave device wherein the third layer includes titanium.

In some embodiments, the techniques described herein relate to a surface acoustic wave device wherein the piezoelectric layer includes lithium tantalate or lithium niobate.

In some embodiments, the techniques described herein relate to a surface acoustic wave device wherein the third layer is thinner than the first layer.

In some embodiments, the techniques described herein relate to a surface acoustic wave device wherein the third layer is thinner than the second layer.

In some embodiments, the techniques described herein relate to a surface acoustic wave device wherein a thickness of the second layer is in a range between 1.8 and 2.2 times a thickness of the first layer.

In some embodiments, the techniques described herein relate to a surface acoustic wave device further including a support substrate and a functional layer between the support substrate and the piezoelectric layer.

In some embodiments, the techniques described herein relate to a surface acoustic wave device wherein the second layer has a sidewall that extends between a bottom side facing the third layer and a top side opposite the bottom side, an angle between the sidewall and the bottom side is in a range between 45 degrees and 95 degrees.

In some embodiments, the techniques described herein relate to a surface acoustic wave device wherein a first width of the first layer is greater than a second width of the second layer.

In some embodiments, the techniques described herein relate to a surface acoustic wave device wherein the sidewall of the second layer is offset from a sidewall of the first layer by an offset length in a range between 0.01 L and 0.08 L, where L is a wavelength of L of a wave generated by the surface acoustic wave device.

In some embodiments, the techniques described herein relate to a surface acoustic wave device wherein the multi-layer interdigital transducer electrode further includes a fourth layer between the first layer and the third layer.

In some embodiments, the techniques described herein relate to a surface acoustic wave device wherein the multi-layer interdigital transducer electrode further includes a fifth layer between the third layer and the fourth layer, the fourth layer includes the same material as the second layer.

In some embodiments, the techniques described herein relate to a surface acoustic wave device further including a passivation layer over the multi-layer interdigital transducer electrode.

In some aspects, the techniques described herein relate to a surface acoustic wave device including: a piezoelectric layer; and a multi-layer interdigital transducer electrode in electrical communication with the piezoelectric layer, the multi-layer interdigital transducer electrode including a first layer, a second layer, and a third layer between the first layer and the second layer, the second layer being more flexible than the first and second layers, and the third layer being more flexible than the first layer.

In some embodiments, the techniques described herein relate to a surface acoustic wave device wherein the first layer includes molybdenum, tungsten, platinum, or ruthenium.

In some embodiments, the techniques described herein relate to a surface acoustic wave device wherein the second layer includes aluminum and the third layer includes titanium.

In some aspects, the techniques described herein relate to a surface acoustic wave device including: a piezoelectric layer; and a multi-layer interdigital transducer electrode in electrical communication with the piezoelectric layer, the multi-layer interdigital transducer electrode including a first layer, a second layer, and a third layer between the first layer and the second layer, the second layer includes aluminum, and the third layer includes titanium.

In some embodiments, the techniques described herein relate to a surface acoustic wave device wherein the third layer being thinner than the first layer and the second layer.

In some aspects, the techniques described herein relate to a surface acoustic wave device including: a piezoelectric layer; and a multi-layer interdigital transducer electrode in electrical communication with the piezoelectric layer, the multi-layer interdigital transducer electrode including a first flexible layer, a second flexible layer, and a rigid layer between the first and second flexible layers, the first flexible layer positioned between the piezoelectric layer and the rigid layer, the first and second flexible layers being more flexible than the rigid layer.

In some embodiments, the techniques described herein relate to a surface acoustic wave device wherein the multi-layer interdigital transducer electrode further includes a second rigid layer between the piezoelectric layer and the first flexible layer.

In some embodiments, the techniques described herein relate to a surface acoustic wave device wherein the multi-layer interdigital transducer electrode further includes a third rigid layer between the second rigid layer and the piezoelectric layer.

In some embodiments, the techniques described herein relate to a surface acoustic wave device wherein the third rigid layer is denser than the second rigid layer.

In some embodiments, the techniques described herein relate to a surface acoustic wave device further including a passivation layer over the multi-layer interdigital transducer electrode.

In some embodiments, the techniques described herein relate to a surface acoustic wave device wherein the first flexible layer is thinner than the second flexible layer.

In some embodiments, the techniques described herein relate to a surface acoustic wave device wherein the rigid layer is thinner than the second flexible layer.

In some embodiments, the techniques described herein relate to a surface acoustic wave device further including a support substrate and a functional layer between the support substrate and the piezoelectric layer.

In some aspects, the techniques described herein relate to a surface acoustic wave device including: a piezoelectric layer; and a multi-layer interdigital transducer electrode in electrical communication with the piezoelectric layer, the multi-layer interdigital transducer electrode including a first low-density layer having a first mass density, a second low-density layer having a second mass density, and a high-density layer having a third mass density greater than the first and second mass densities, the first low-density layer positioned between the second low-density layer and the piezoelectric layer, the high-density layer positioned between the first and second low-density layers, and a thickness of the first low-density layer being less than a thickness of the second low-density layer.

In some embodiments, the techniques described herein relate to a surface acoustic wave device wherein the first low-density layer includes aluminum.

In some embodiments, the techniques described herein relate to a surface acoustic wave device wherein the second low-density layer includes aluminum.

In some embodiments, the techniques described herein relate to a surface acoustic wave device wherein the high-density layer includes titanium.

In some embodiments, the techniques described herein relate to a surface acoustic wave device wherein a thickness of the high-density layer being less than the thickness of the first low-density layer and the thickness of the second low-density layer.

In some embodiments, the techniques described herein relate to a surface acoustic wave device wherein the multi-layer interdigital transducer electrode further includes a second high-density layer having a fourth mass density that is greater than the mass density of the first and second mass densities, the second high-density layer is positioned between the piezoelectric layer and the first low-density layer.

In some embodiments, the techniques described herein relate to a surface acoustic wave device wherein the multi-layer interdigital transducer electrode further includes a third high-density layer having a fifth mass density that is greater than the third mass density and the fourth mass density.

In some embodiments, the techniques described herein relate to a surface acoustic wave device further including a passivation layer over the multi-layer interdigital transducer electrode.

In some aspects, the techniques described herein relate to a surface acoustic wave device including: a piezoelectric layer; and a multi-layer interdigital transducer electrode in electrical communication with the piezoelectric layer, the multi-layer interdigital transducer electrode including a first layer, a second layer, and a transition structure between the first layer and the second layer, the first layer being more rigid than the second layer, the transition structure including a material that has a density greater than 2690 kg/m3.

In some embodiments, the techniques described herein relate to a surface acoustic wave device further including a passivation layer over the multi-layer interdigital transducer electrode.

In some embodiments, the techniques described herein relate to a surface acoustic wave device wherein the transition structure includes a plurality of layers.

In some embodiments, the techniques described herein relate to a surface acoustic wave device wherein the plurality of layers include an aluminum layer and a titanium layer.

### BRIEF DESCRIPTION OF THE DRAWINGS

Embodiments of this disclosure will now be described, by way of non-limiting example, with reference to the accompanying drawings.

FIG. 1A is a schematic cross-sectional side view of a surface acoustic wave (SAW) device according to an embodiment.

FIG. 1B is a graph showing stress displacement in two different interdigital transducer electrode structures (IDT Structures A and B).

FIGS. 1C and 1D are schematic cross-sectional views of IDT Structures A and B.

FIGS. 2A to 2D show simulated strain distributions in different SAW devices.

FIG. 2E is a graph showing simulated mises strain in the SAW device of FIG. 1A.

FIG. 3 is a schematic cross-sectional side view of a SAW device 3 according to an embodiment.

FIG. 4A to 4C shows a simulated strain distributions in different SAW devices.

FIG. 4D is a graph showing simulated destruction time over input power for the SAW devices shown in FIGS. 4A to 4C.

FIG. 5 is a schematic cross-sectional side view of a SAW device according to an embodiment.

FIGS. 6A-6C are schematic cross-sectional side views of the SAW device of FIG. 1A showing simulated strain distributions therein with different sidewall angles.

FIG. 6D is a graph showing simulated maximum strain values at different sidewall angles.

FIG. 7 is a graph showing simulated maximum strain values at different sidewall angles and offset lengths.

FIG. 8A is a schematic diagram of a transmit filter that includes a surface acoustic wave resonator according to an embodiment.

FIG. 8B is a schematic diagram of a receive filter that includes a surface acoustic wave resonator according to an embodiment.

FIG. 9 is a schematic diagram of a radio frequency module that includes a surface acoustic wave resonator according to an embodiment.

FIG. 10 is a schematic diagram of a radio frequency module that includes filters with surface acoustic wave resonators according to an embodiment.

FIG. 11 is a schematic block diagram of a module that includes an antenna switch and duplexers that include a surface acoustic wave resonator according to an embodiment.

FIG. 12A is a schematic block diagram of a module that includes a power amplifier, a radio frequency switch, and duplexers that include a surface acoustic wave resonator according to an embodiment.

FIG. 12B is a schematic block diagram of a module that includes filters, a radio frequency switch, and a low noise amplifier according to an embodiment.

FIG. 13A is a schematic block diagram of a wireless communication device that includes a filter with a surface acoustic wave resonator in accordance with one or more embodiments.

FIG. 13B is a schematic block diagram of another wireless communication device that includes a filter with a surface acoustic wave resonator in accordance with one or more embodiments.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic wave filters can filter radio frequency (RF) signals in a variety of applications, such as in an RF front end of a mobile phone. An acoustic wave filter can be implemented with surface acoustic wave (SAW) devices. Certain SAW devices may be referred to as SAW resonators. Any features of the SAW resonators discussed herein can be implemented in any suitable SAW device such as a multilayer piezoelectric substrate (MPS) SAW device.

A multilayer piezoelectric substrate surface acoustic wave (MPS-SAW) device can include a support substrate, a piezoelectric layer over the support substrate, and an interdigital transducer (IDT) electrode in electrical communication with the piezoelectric layer. A multilayer IDT electrode structure that includes two or more metal layers can be implemented in a SAW device to reduce the size of the SAW device. The thermal dissipation ability of the MPS SAW device is generally greater than other types of SAW devices, such as a temperature compensated (TC) SAW device that includes a temperature compensation layer over the IDT electrode.

In general, high quality factor (Q), large effective electromechanical coupling coefficient (k2), high frequency ability, and spurious free response can be significant aspects for acoustic wave elements to enable low-loss filters, delay lines, stable oscillators, and sensitive sensors. Also, high power durability can be a significant aspect for enabling a reliable SAW device. Various properties, such as materials and dimensions, of the components in a SAW device can affect the quality value, (Q), the coupling coefficient (k2), the frequency ability, and/or the power durability. A precise selection of, for example, the materials and dimensions of the multilayer IDT electrode can be significant for providing a multilayer piezoelectric substrate (MPS) surface acoustic wave (SAW) device with a relatively high quality factor (Q), a relatively large effective electromechanical coupling coefficient (k2), a relatively high frequency ability, and a relatively high power durability.

Also, reduced nonlinearity can be desirable in some SAW devices as it can affect the performance (e.g., the quality factor) of the SAW devices. Nonlinearity in SAW devices can be the deviation from a proportional relationship between the input signal and the output response, which can result in signal distortion and unwanted harmonics. Improving nonlinearity can be important because it enhances the device's performance by reducing signal degradation, maintaining signal integrity, and ensuring high-fidelity transmission, which can be significant in applications like telecommunications and signal processing. A relatively high stress or strain concentration in the IDT electrode can be one of the causes for nonlinearity. Nonlinear behavior can cause higher-order modes, such as third-order harmonics, to appear, which are multiples of the fundamental frequency and further degrade the signal quality in some applications. Therefore, there is a need for nonlinearity improvement in SAW devices to achieve optimal performance and reliable operation in critical applications.

Various embodiments disclosed herein relate to SAW devices, such as MPS-SAW devices, with a multi-layer interdigital transducer electrode that are configured to provide a reduced stress or strain concentration, a reduced nonlinearity, a relatively high quality factor (Q), a relatively large effective electromechanical coupling coefficient (k2), a relatively high frequency ability, and/or a relatively high power durability. A SAW device according to various embodiments includes a piezoelectric layer and a multi-layer interdigital transducer electrode that is in electrical communication with the piezoelectric layer. In some embodiments, the multi-layer interdigital transducer electrode can include a thirst layer, a second layer, and a third layer between the first and second layers. The first layer can be positioned between the piezoelectric layer and the second layer. A first mass density of the first layer is greater than a second mass density of the second layer and a third mass density of the third layer, and the third density is greater than the second mass density

In some embodiments, the multi-layer interdigital transducer electrode can include a first flexible (e.g., low-density) layer having a first mass density, a second flexible layer having a second mass density, and a rigid (e.g., high-density) layer having a third mass density. The third mass density can be greater than the first and second mass densities. The first flexible layer is positioned between the second flexible layer and the piezoelectric layer. The rigid layer is positioned between the first and second flexible layers. A thickness of the first flexible layer can be less than a thickness of the second flexible layer.

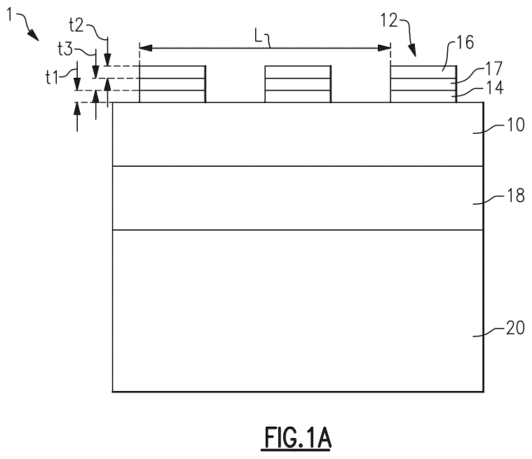

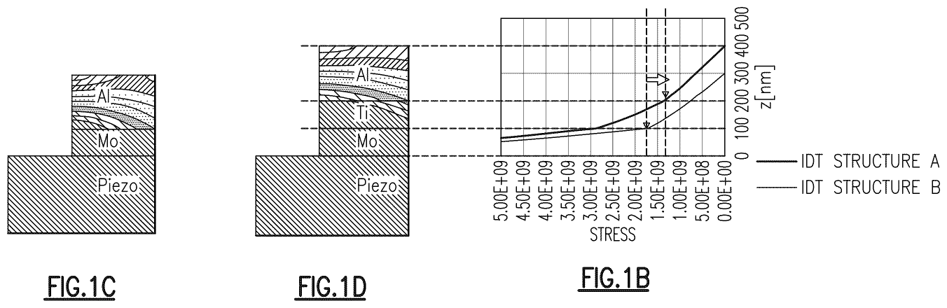

FIG. 1A is a schematic cross-sectional side view of a surface acoustic wave (SAW) device 1 according to an embodiment. The illustrated SAW device 1 can include a piezoelectric layer 10, an interdigital electrode transducer (IDT) electrode 12 that includes a first layer 14, a second layer 16, and a third layer 17, a functional layer 18 below the piezoelectric layer 10, and a support substrate 20 below the functional layer 18. The IDT electrode 12 is in electrical communication with the piezoelectric layer 10. The SAW device 1 is an example of a multilayer piezoelectric substrate (MPS) SAW device. The SAW device 1 generates a surface acoustic wave having a wavelength A or L. In some embodiments, the SAW device 1 may include an overcoat layer (not shown) that has a thickness of 0.1 L or less.

The piezoelectric layer 10 can include any suitable piezoelectric layer, such as a lithium based piezoelectric layer. In some embodiments, the piezoelectric layer 10 can be a lithium tantalate (LT) layer. For example, the piezoelectric layer 10 can be an LT layer having a cut angle of 20° (20° Y-cut X-propagation LT) or a cut angle of 60° (60° Y-cut X-propagation LT). For example, the piezoelectric layer 10 can be 20±10° Y-cut LT, 42±25° Y-cut LT, 42±20° Y-cut LT, 42±15° Y-cut LT, 42±10° Y-cut LT, 42±5° Y-cut LT, 60±20° Y-cut LT, 60±15° Y-cut LT, 60±10° Y-cut LT, or 60±5° Y-cut LT. Any other suitable piezoelectric material, such as a lithium niobate (LN) layer, can be used as the piezoelectric layer 10. For example, the piezoelectric layer 10 can be an LN layer having a cut angle of about 118° (118° Y-cut X-propagation LN) or more or a cut angle of about 132° (132Y-cut X-propagation LN) or less. For example, the piezoelectric layer 10 can be 125±20° Y-cut LN, 125±15° Y-cut LN, 125±10° Y-cut LN, or 125±5° Y-cut LN. A thickness of the piezoelectric layer 10 can be selected based on a wavelength/or L of a surface acoustic wave generated by the SAW device 1 in certain applications. In some embodiments, the wavelength L can be in a range between, for example, 3 micrometers and 6 micrometers, 3.5 micrometers and 6 micrometers, 3 micrometers and 5.5 micrometers, or 3.5 micrometers and 5.5 micrometers. The piezoelectric layer 10 can be sufficiently thick to avoid significant frequency variation. For example, the thickness of the piezoelectric layer 10 can be in a range of 0.1 L to 0.5, 0.1 L to 0.3 L, or 0.1 L to 0.2 L. Selecting the thickness of the piezoelectric layer 10 from these ranges can be critical in avoiding significant frequency variation and providing sufficient temperature coefficient of frequency for the SAW device 1. In some embodiments, the piezoelectric layer 10 can include lithium tantalate (LT) and lithium niobate (LN).

The illustrated IDT electrode 12 includes a first layer 14, a second layer 16, and a third layer 17. One of the first layer 14, the second layer 16, and the third layer 17 can be more electrically conductive than the other, and the other ones can be more durable (e.g., resistive to metal fatigue). In some embodiments, the first layer 14, the second layer 16, or the third layer 17 can have a higher mass density and/or higher Young's modulus than the other layers.

The first layer 14 of the IDT electrode 12 can be referred to as a lower electrode layer. The first layer 14 of the IDT electrode 12 can be positioned between the second layer 16 of the IDT electrode 12 and the piezoelectric layer 10. As illustrated, the first layer 14 of the IDT electrode 12 can have a first side in physical contact with the piezoelectric layer 10 and a second side in physical contact with the third layer 17 of the IDT electrode 12. The second layer 16 of the IDT electrode 12 can be referred to as an upper electrode layer. The second layer 16 of the IDT electrode 12 can be positioned over the first layer 14 of the IDT electrode 12. As illustrated, the second layer 16 of the IDT electrode 12 can have a first side in physical contact with the third layer 17 of the IDT electrode 12 and a second side opposite the first side. The third layer 17 can be referred to as a middle or intermediate electrode layer. The third layer 17 of the IDT electrode 12 can be positioned between the first layer 14 and the second layer 16 of the IDT electrode 12. As illustrated, the third layer 17 of the IDT electrode 12 can have a first side in physical contact with the first layer 17 of the IDT electrode 12 and a second side in physical contact with the second layer 16. The third layer 17 can suppress metal movement in the second layer 16 during operation of the SAW device 1. Such suppression of metal in the second layer 16 can improve power durability and/or extend the lifetime of the SAW device 1.

The IDT electrode 12 can include any suitable IDT electrode material. For example, the IDT electrode can include molybdenum (Mo), aluminum (Al), copper (Cu), magnesium (Mg), titanium (Ti), tungsten (W), the like, or any suitable combination thereof. The IDT electrode 12 may include alloys, such as AlMgCu, AlCu, etc. A mass loading exchange rate of the first layer 14 can be greater than a mass loading exchange rate of the second layer 16. A mass loading exchange rate of the third layer 17 can be greater than the mass loading exchange rate of the second layer 16 and less than the mass loading exchange rate of the first layer 14. A mass loading exchange rate can be determined based on the material of the first layer 14, the second layer 16, or the third layer and mass loafing effect provided by the first layer 14, the second layer 16, or the third layer 17.

Table 1 provided below shows normalized mass loading exchange rates of aluminum (Al), molybdenum (Mo), tungsten (W), platinum (Pt), ruthenium (Ru), titanium (Ti), copper (Cu), and gold (Au) normalized by the mass loading exchange rate of molybdenum (Mo). Table 1 also shows mass densities and Young's moduli of the materials.

TABLE 1

| | Exchange rate | Density | Young's modulus |
|---|---|---|---|
| Material | normalized by Mo | p[kg/m3] | E[N/m\hat{ }2] |
| Al | 0.47 | 2690 | 6.773E+10 |
| Mo | 1.00 | 10220 | 3.654E+11 |
| W | 1.87 | 19300 | 3.450E+11 |
| Pt | 2.27 | 17700 | 1.520E+11 |
| Ru | 1.17 | 12410 | 4.140E+11 |
| Ti | 0.57 | 4500 | 1.161E+11 |
| Cu | 1.03 | 8930 | 1.297E+11 |
| Au | 2.68 | 19300 | 8.085E+10 |

The mass loading exchange rate of the material can generally be proportional to the mass density of the material. The first layer 14 has a thickness t1. In some embodiments, the thickness t1 of the first layer 14 can be determined at least in part on the normalized mass loading exchange rate shown in Table 2. In some embodiments, the thickness t1 of the first layer 14 can be determined at least in part by the density of a material. For example, the thickness t1 of the first layer 14 can be in a range between 0.01 L and 0.055 L, 0.01 L and 0.05 L, 0.015 L and 0.055 L, 0.01 L and 0.05 L, or 0.02 L and 0.05 L multiplied by a normalized value of the first mass density normalized by a mass density of molybdenum. More specifically, the thickness t1 of the first layer 14 can be in a range between 0.01 L and 0.055 L, 0.01 L and 0.05 L, 0.015 L and 0.055 L, 0.01 L and 0.05 L, or 0.02 L and 0.05 L, multiplied by (10220/p) in which p is the density of the material used for the first layer 14. In some embodiments, for example, the first layer 14 can be molybdenum (Mo) and the second layer 16 can be aluminum (Al), or the first layer 14 can be tungsten (W) and the second layer 16 can be aluminum (Al).

The second layer 16 has a thickness t2. The thickness t1 of the first layer 14 and the thickness t2 of the second layer 16 can be determined based at least in part on the wavelength L of surface acoustic wave generated by the SAW device 1. In some embodiments, the thickness t1 of the first layer 14 can be in a range between 0.01 L and 0.055 L, 0.01 L and 0.05 L, 0.015 L and 0.055 L, or 0.01 L and 0.05 L. In some embodiments, the thickness t2 of the second layer 16 can be in a range between 0.02 L and 0.08 L, 0.03 L and 0.08 L, 0.04 L and 0.08 L, 0.02 L and 0.06 L, 0.045 L and 0.08 L, 0.04 L and 0.07 L, 0.045 L and 0.07 L, or 0.03 L and 0.06 L. The thickness t2 of the second layer 16 can be greater than the thickness t1 of the first layer 14. For example, the thickness t2 of the second layer 16 can be in a range between 1.5 and 2.5 times or between 1.8 and 2.2 times the thickness t1 of the first layer 14. In some embodiments, the second layer 16 can have a minimum thickness of about 100 nanometers, about 120 nanometers, or about 150 nanometers. Selecting the thicknesses t1, t2 of the first and second layers 14, 16 from the thickness ranges and ratios disclosed herein can be critical in providing a more reliable, more durable SAW device with a relatively high quality factor (Q) as compared to a similar SAW device with IDT layer thickness outside of these ranges.

The third layer 17 has a thickness t3. In some embodiments, the thickness t3 of the third layer 17 can be thinner than the second thickness t2 of the second layer 16. For example, the thickness t3 can be in a range between 0.05 and 0.7 times, 0.05 and 0.5 times, 0.1 and 0.5 times, 0.1 and 0.2 times the thickness t2 of the second layer 16. In some embodiments, the thickness t3 of the third layer 17 can be generally similar to or thinner than the thickness t1 of the first layer 14. For example, the thickness t3 can be in a range between 0.1 and 1 times, 0.25 and 1 times, 0.1 and 0.5 times, 0.1 and 0.2 times the thickness t1 of the first layer 14.

Table 2 provided below shows example thicknesses of the first and second layers 14, 16 when the first layer 14 is a molybdenum layer and the second layer 16 is an aluminum layer for the wavelengths L of 4 micrometers (μm), 5.5 μm, and 4.5 μm. In some embodiments, the first and second layers 14, 16 can have thicknesses within 10% or within 5% of the values provided in Table 2.

TABLE 2

| L (μm) | Al (nm) | Mo (nm) | Al (L) | Mo (L) | Al/Mo ratio |
|---|---|---|---|---|---|
| 4 | 200 | 100 | 0.05 | 0.025 | 2 |
| 5.5 | 330 | 160 | 0.06 | 0.029 | 2.063 |
| 4.5 | 330 | 160 | 0.073 | 0.036 | 2.063 |
| 5.5 | 200 | 250 | 0.036 | 0.045 | 0.8 |
| 5.5 | 400 | 140 | 0.073 | 0.025 | 2.857 |

In some embodiments, in addition to the first layer 14 and the second layer 16 listed in Table 2, a titanium layer can be included as the third layer 17. The third layer 17 can be in a range between, for example, 10 nm and 100 nm, 10 nm and 50 nm, 25 nm and 75 nm, or 25 nm and 100 nm.

Table 3 provided below shows example thicknesses of the first and second layers 14, 16 when the first layer 14 is a tungsten layer and the second layer 16 is an aluminum layer for the wavelength L of 5.5 μm. In some embodiments, the first and second layers 14, 16 can have thicknesses within 10% or within 5% of the values provided in Table 3.

TABLE 3

| L (μm) | Al (nm) | W (nm) | Al (L) | W (L) | Al/W ratio |
|---|---|---|---|---|---|
| 5.5 | 180 | 80 | 0.033 | 0.015 | 2.25 |

In some embodiments, in addition to the first layer 14 and the second layer 16 listed in Table 3, a titanium layer can be included as the third layer 17. The third layer 17 can be in a range between, for example, 10 nm and 100 nm, 10 nm and 50 nm, 25 nm and 75 nm, or 25 nm and 100 nm.

In some embodiments, a width of the first layer 14 can be different from a width of the second layer 16. For example, the width of the first layer 14 can be greater than the width of the second layer 16. In some embodiments, a width of the third layer 17 can be different from the width of the first layer 14 and/or the width of the second layer 16. For example, the width of the third layer 17 can be less than the width of the first layer 14 and/or greater than the width of the second layer 16. Though the illustrated IDT electrode 12 is located on a surface the piezoelectric layer 10, in some other embodiments, the IDT electrode 12 can be at least partially within the piezoelectric layer 10 or embedded in the piezoelectric layer 10.

The illustrated surface acoustic wave resonator 1 includes the functional layer 18 between the piezoelectric layer 10 and the support substrate 20. The functional layer 18 can be referred to as an intermediate layer. The functional layer 18 can be, for example, a single crystal layer. In some embodiments, the functional layer 18 can be a silicon oxide layer (e.g., a silicon dioxide (SiO₂) layer. In some embodiment, the functional layer 18 can function as an adhesion layer. In some embodiments, a thickness of the functional layer 18 can be the same as, generally similar to, or thinner than the thickness of the piezoelectric layer 10.

The support substrate 20 can be any suitable substrate layer, such as a silicon layer, a quartz layer, a ceramic layer, a glass layer, a spinel layer, a magnesium oxide spinel layer, a sapphire layer, a diamond layer, a silicon carbide layer, a silicon nitride layer, an aluminum nitride layer, an aluminum oxide layer, or the like. The support substrate 20 can have a relatively high acoustic impedance. For example, the support substrate 20 can have a higher impedance than an impedance of the piezoelectric layer 10 and a higher thermal conductivity than a thermal conductivity of the piezoelectric layer 10. In some embodiments, there can be a trap rich layer that may be formed at or near a surface of the support substrate 20 facing the functional layer 18. One or more additional layers can be inserted between the functional layer 18 and the support substrate 20 to prevent or mitigate the unwanted electrical leakage on the surface of the support substrate 20. For example, one or more layers that include Poly-Si, amorphous Si, Porous Si, SiN, and/or AlN can be disposed between the functional layer 18 and the support substrate 20.

The materials, the thicknesses, and the ratio between the thicknesses of the first layer 14, the second layer 16, and the third layer 17 of the IDT electrode 12 can significantly affect strain or stress concentration at a boundary between the second and third layers 16, 17 and/or a boundary between the first and third layers 14, 17, and the instant destruction power (dBm) of a SAW device.

FIG. 1B is a graph showing stress displacement in two different IDT electrode structures (IDT Structures A and B). FIGS. 1C and 1D are schematic cross-sectional views of IDT Structures A and B. The stress can be a product of the strain and the stiffness. IDT Structure A includes a dual-layer IDT electrode that includes an aluminum layer and a molybdenum layer between the piezoelectric layer and the aluminum layer, and IDT Structure B includes a three-layer IDT electrode that includes an aluminum layer, a molybdenum layer between the piezoelectric layer and the aluminum layer, and a titanium layer between the aluminum layer and the molybdenum layer. The three-layer IDT electrode can be an example of the IDT electrode 12 of FIG. 1A in which the first layer 14 includes molybdenum, the second layer 16 includes aluminum, and the third layer 17 includes titanium. FIG. 1B indicates that the three-layer, aluminum-titanium-molybdenum IDT electrode can suppress formation of the third order harmonic by reducing stress concentration in the IDT electrode, thereby improving nonlinearity. More specifically, the third layer 17 (the titanium layer) can provide reduced maximum stress in the second layer 16 (the aluminum layer). Because the second layer 16 (the aluminum layer) can be one of the origins of nonlinearity, the reduced stress in the second layer 16 (the aluminum layer) can improve the nonlinearity.

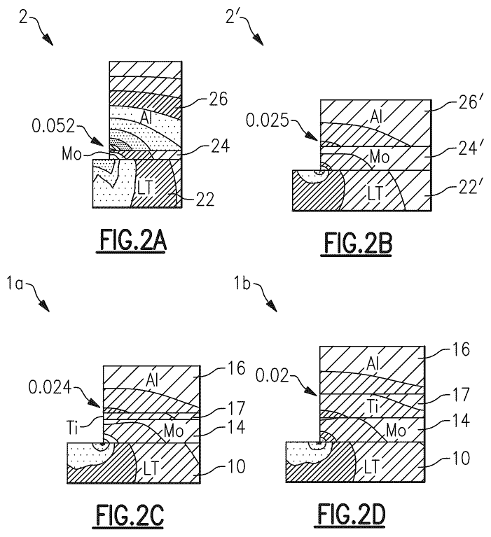

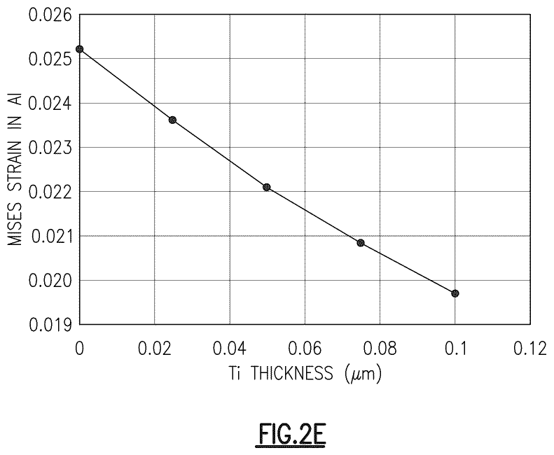

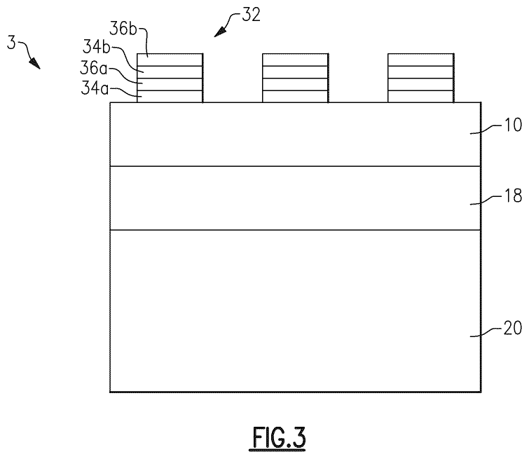

FIG. 2A shows a simulated strain distribution in a portion of a SAW device 2. Unless otherwise noted, the components of the SAW device 2 shown in FIG. 2A may be structurally and/or functionally the same as or generally similar to like components disclosed herein. The SAW device 2 shown in FIG. 2A includes a lithium tantalate piezoelectric layer 22, a molybdenum layer 24 that has a thickness of 40 nm, and an aluminum layer 26 that has a thickness of 400 nm. FIG. 2A indicates that the strain is concentrated at an edge of the aluminum layer 26 that contacts the molybdenum layer 24. At the edge of the aluminum layer 26, the strain is about 0.052. Such concentration of strain at a portion of the aluminum layer 26 can damage the aluminum layer 26 due to, for example, metal fatigue.

FIG. 2B shows a simulated strain distribution in a portion of a SAW device 2′ according to an embodiment. Unless otherwise noted, the components of the SAW device 2′ shown in FIG. 2B may be structurally and/or functionally the same as or generally similar to like components disclosed herein. The SAW device 2′ includes a lithium tantalate piezoelectric layer 22, a molybdenum layer 24′ that has a thickness of 100 nm, and an aluminum layer 26′ that has a thickness of 200 nm. FIG. 2B indicates that the strain at an edge of the aluminum layer 26′ that contacts the molybdenum layer 24′ is about 0.025 which is significantly lower than the strain at the edge of the aluminum layer 26 in FIG. 2A.

FIGS. 2C and 2D show simulated strain distribution in SAW devices 1a, 1b with different IDT electrode thickness configurations. Unless otherwise noted, the components of the SAW devices 1a, 1b shown in FIGS. 2C and 2D may be structurally and/or functionally the same as or generally similar to like components disclosed herein. In FIGS. 2C and 2D, a lithium tantalate layer is used as the piezoelectric layer 10, a molybdenum layer is used as the first layer 14, an aluminum layer is used as the second layer 16, and a titanium layer is used as the third layer 17. In FIG. 2C, the thickness t1 of the first layer 14 is 100 nm, the thickness t2 of the second layer 16 is 200 nm, and the thickness t3 of the third layer 17 is 25 nm. In FIG. 2D, the thickness t1 of the first layer 14 is 100 nm, the thickness t2 of the second layer 16 is 200 nm, and the thickness t3 of the third layer 17 is 100 nm.

FIG. 2C indicates that the strain at an edge of the second layer 16 is about 0.024 and FIG. 2D indicates that the strain at the edge of the second layer 16 is about 0.02. FIGS. 2C and 2D indicate that the third layer 17 positioned between the first layer 14 and the second layer 16 can contribute to further reducing the strain concentration at an edge of the second layer 16.

FIG. 2E is a graph showing simulated mises strain in the second layer 16 of the SAW device 1 at different thicknesses t3 of the third layer 17. In FIG. 2E, a lithium tantalate layer is used as the piezoelectric layer 10, a molybdenum layer is used as the first layer 14, an aluminum layer is used as the second layer 16, and a titanium layer is used as the third layer 17. In the simulation, the thickness t1 of the first layer 14 is set to 100 nm, the thickness t2 of the second layer 16 is set to 200 nm, and the thickness t3 of the third layer 17 is swept from 0 to 0.1 μm. FIG. 2E indicates that when the thickness t3 is increased, the mises strain in the second layer 16 tends to decrease.

As described herein, suitably positioning a metal layer with a higher density, a higher young's modulus, and/or a higher exchange rate in an IDT electrode can suppress metal movement in a metal layer with a lower density, a lower young's modulus, and/or a lower exchange rate during operation of a SAW device, which can contribute to improving power durability and/or extending the lifetime of the SAW device. Arrangements of different metal layers in an IDT electrode can significantly affect the performance of the SAW device. FIG. 3 illustrates an example arrangement of metal layers in an IDT electrode that is different from that shown in FIG. 1A.

FIG. 3 is a schematic cross-sectional side view of a surface acoustic wave (SAW) device 3 according to an embodiment. Unless otherwise noted, the components of the SAW device 3 shown in FIG. 3 may be structurally and/or functionally the same as or generally similar to like components disclosed herein.

The SAW device 3 can include a piezoelectric layer 10, an interdigital electrode transducer (IDT) electrode 32 that includes a first rigid layer 34a, a first flexible layer 36a, a second rigid layer 34b, and a second flexible layer 36b, a functional layer 18 below the piezoelectric layer 10, and a support substrate 20 below the functional layer 18. The IDT electrode 32 is in electrical communication with the piezoelectric layer 10. The SAW device 3 is an example of a multilayer piezoelectric substrate (MPS) SAW device.

In the IDT electrode 32, the first rigid layer 34a and the second rigid layer 34b can have a higher density, a higher young's modulus, and/or a higher exchange rate than the first flexible layer 36a and the second flexible layer 36b. In some embodiments, the first rigid layer 34a and/or the second rigid layer 34b can have a density greater than 2690 kg/m3, greater than 3000 kg/m3, or greater than 4000 kg/m3, a young's modulus higher than 6.773E+10 N/m\hat{ }2, higher than 9E+10 N/m\hat{ }2, or higher than 1E+11 N/m\hat{ }2, and/or an exchange rate normalized by Mo greater than 0.47, greater than 0.5, or greater than 0.55. In some embodiments, the first flexible layer 36a and/or the second flexible layer 36b can have a density equal to or less than 2690 kg/m3, equal to or less than 3000 kg/m3, or equal to or less than 4000 kg/m3, a young's modulus of equal to or less than 6.773E+10 N/m\hat{ }2, equal to or less than 9E+10 N/m\hat{ }2, or equal to or less than 1E+11 N/m\hat{ }2, and/or an exchange rate normalized by Mo equal to or less than 0.47, equal to or less than 0.5, or equal to or less than 0.55.

In some embodiments, the rigid layer 34a and the second rigid layer 34b can have the same material and the first flexible layer 36a and the second flexible layer 36b can have the same material. For example, the rigid layer 34a and the second rigid layer 34b can be titanium layers and the first flexible layer 36a and the second flexible layer 36b can be aluminum layers. In such embodiments, the aluminum grain size may be reduced when the aluminum is provided on a surface of the titanium layer. The first rigid layer 34a can have a material property and/or a structure similar to those of the first layer 14 of the SAW device 1 described herein. The second rigid layer 34b can have a material property and/or a structure similar to those of the third layer 17 of the SAW device 1 described herein. The first flexible layer 36a can have a material property and/or a structure similar to those of the second layer 16 of the SAW device 1 described herein. The second flexible layer 36b can have a material property and/or a structure similar to those of the second layer 16 of the SAW device 1 described herein.

A thickness of the second flexible layer 36b can be equal to or greater than a thickness of the first flexible layer 36a. The first and second rigid layers 34a, 34b can be relatively thin. For example, the first and second rigid layers 34a, 34b can be thinner than the first flexible layer 36a and/or the second flexible layer 36b. In some embodiments, the first rigid layer 34a can be in a range between 1% and 10% or 2% and 4% of the total thickness of the IDT electrode 32 or in a range between 4 nm and 40 nm or 8 nm and 16 nm. In some embodiments, the second rigid layer 34b can be in a range between 1% and 10% or 2% and 4% of the total thickness of the IDT electrode 32 or in a range between 4 nm and 40 nm or 8 nm and 16 nm. In some embodiments, the first flexible layer 36a can be in a range between 40% and 60%, 45% and 55%, 4% and 10%, or 4% and 6% of the total thickness of the IDT electrode 32 or in a range between 160 nm and 240 nm, 180 nm and 220 nm, 16 nm and 40 nm, or 16 nm and 24 nm.

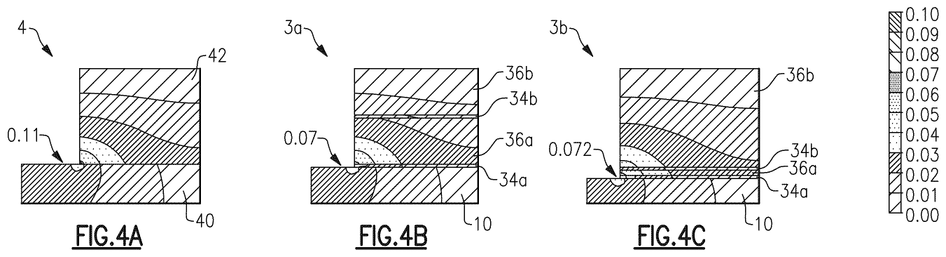

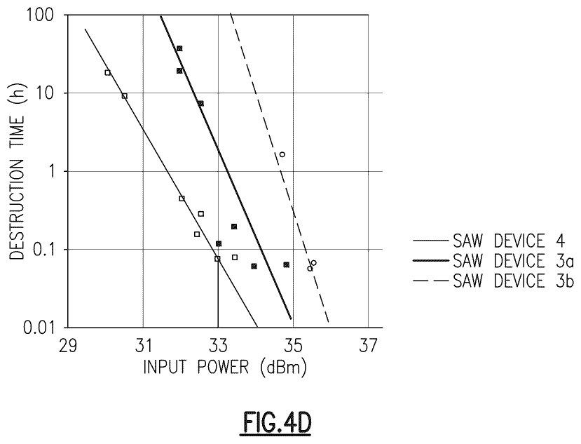

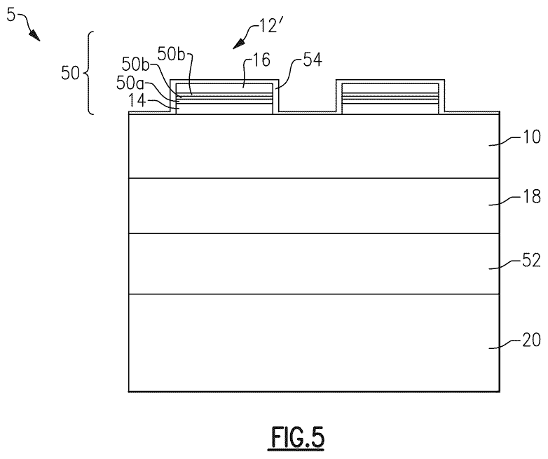

The multilayer IDT electrode structure of FIG. 3 can reduce strain in the IDT electrode as compared to a single layer IDT electrode structure. FIGS. 4A to 4C compare strain concentration in SAW devices with different IDT structures.

FIG. 4A shows a simulated strain distribution in a portion of a SAW device 4. The SAW device 4 includes a lithium tantalate piezoelectric layer 40 and a 400 nm thick aluminum-copper-magnesium alloy IDT electrode 42. FIG. 4B shows a simulated strain distribution in a portion of a SAW device 3a. The SAW device 3a includes a lithium tantalate piezoelectric layer as the piezoelectric layer 10, a 10 nm thick titanium layer as the first rigid layer 34a, a 192 nm thick aluminum layer as the first flexible layer 36a, a 10 nm thick titanium layer as the second rigid layer 34b, and a 192 nm thick aluminum layer as the second flexible layer 36b. FIG. 4B shows a simulated strain distribution in a portion of a SAW device 3b. The SAW device 3a includes a lithium tantalate piezoelectric layer as the piezoelectric layer 10, a 10 nm thick titanium layer as the first rigid layer 34a, a 192 nm thick aluminum layer as the first flexible layer 36a, a 10 nm thick titanium layer as the second rigid layer 34b, and a 192 nm thick aluminum layer as the second flexible layer 36b. The strain shown in FIGS. 4A to 4C is VonMises strain.

The maximum strain in the SAW device 4 is about 0.11, the maximum strain in the SAW device 3a is about 0.07, and the maximum strain in the SAW device 3b is about 0.072. FIGS. 4A to 4C indicate that the strain can be reduced by including the first and second rigid layers 34a, 34b

FIG. 4D is a graph showing simulated destruction time over input power for the three SAW devices 4, 3a, 3b shown in FIGS. 4A to 4C. The results of FIG. 4D indicate that the SAW devices 3a, 3b tend to be more durable than the SAW device 4.

The stress or strain in the IDT electrode can further be reduced by providing a relatively thick passivation layer over the IDT electrode (see FIG. 5). Also, any suitable principles and advantages disclosed herein related to IDT electrodes can be combined as shown in FIG. 5.

FIG. 5 is a schematic cross-sectional side view of a SAW device 5 according to an embodiment. Unless otherwise noted, the components of the SAW device 5 shown in FIG. 5 may be structurally and/or functionally the same as or generally similar to like components disclosed herein.

The SAW device 5 can include a piezoelectric layer 10, an interdigital electrode transducer (IDT) electrode 12′ that includes a first layer 14, a second layer 16, and a transition structure 50, a functional layer 18 below the piezoelectric layer 10, a support substrate 20 below the functional layer 18, a trap-rich layer 52 between the support substrate 20 and the functional layer 18, a passivation layer 54 over the IDT electrode 12′. The IDT electrode 12′ is in electrical communication with the piezoelectric layer 10. The SAW device 5 is an example of a multilayer piezoelectric substrate (MPS) SAW device. The third layer 17 of the SAW device 1 of FIG. 1A is an example of when the transition structure 50 has a single layer structure.

The transition structure 50 can include layers 50a, 50b, 50c. The layer 50a can be structurally and/or functionally equivalent to the first rigid layer 34a of the SAW device 3 of FIG. 3. The layer 50b can be structurally and/or functionally equivalent to the first flexible layer 36a of the SAW device 3 of FIG. 3. The layer 50c can be structurally and/or functionally equivalent to the second rigid layer 34b of the SAW device 3 of FIG. 3. The second layer 16 can be structurally and/or functionally equivalent to the second flexible layer 36b of the SAW device 3 of FIG. 3. The first layer 14 can be structurally and/or functionally equivalent to the second flexible layer 36b of the SAW device 3 of FIG. 3.

In some embodiments, the first layer 14 can be a molybdenum layer, the second layer 16 can be an aluminum layer, the layer 50a can be a titanium layer, the layer 50b can be an aluminum layer, and the layer 50c can be a titanium layer.

The passivation layer 54 can include any suitable material to increase the magnitude of the velocity of the underlying region. In some applications, the passivation layer 54 can include silicon nitride (SiN). In some embodiments, the passivation layer 54 can be patterned such that the acoustic propagation velocity can be adjusted at certain regions. In some instances, the passivation layer 54 can physically protect the IDT electrode 12′. In some instances, the passivation layer 54 can be used for frequency trimming and/or frequency tuning. Therefore, the passivation layer 54 can also be referred to as a frequency trimming layer. The passivation layer 54 can include a silicon nitride (SiN) layer and/or an aluminum oxide (Al₂O₃) layer. In some embodiments, the passivation layer 54 can have a thickness greater than 10 nm. For example, the thickness of the passivation layer 54 can be in a range between 10 nm and 50 nm, 15 nm and 50 nm, 20 nm and 50 nm, 30 nm and 50 nm, 15 nm and 30 nm, or 20 nm and 40 nm.

The trap-rich layer 52 can be a polysilicon layer, an amorphous silicon layer, or the like. The trap-rich layer 52 can have a reduced carrier mobility relative to the support substrate 20. The trap-rich layer 52 can improve the electrical characteristics of the SAW device 5 by increasing the depth and sharpness on the anti-resonance peak.

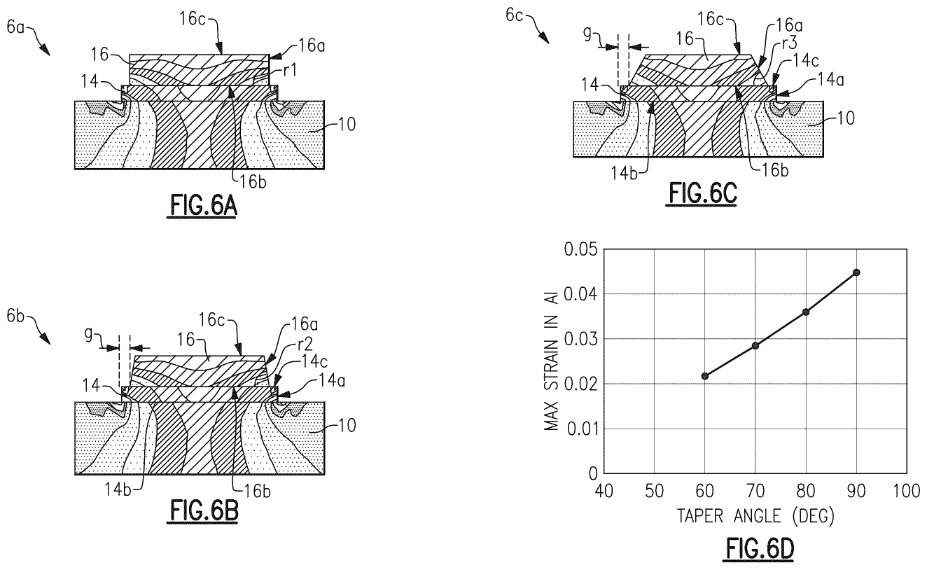

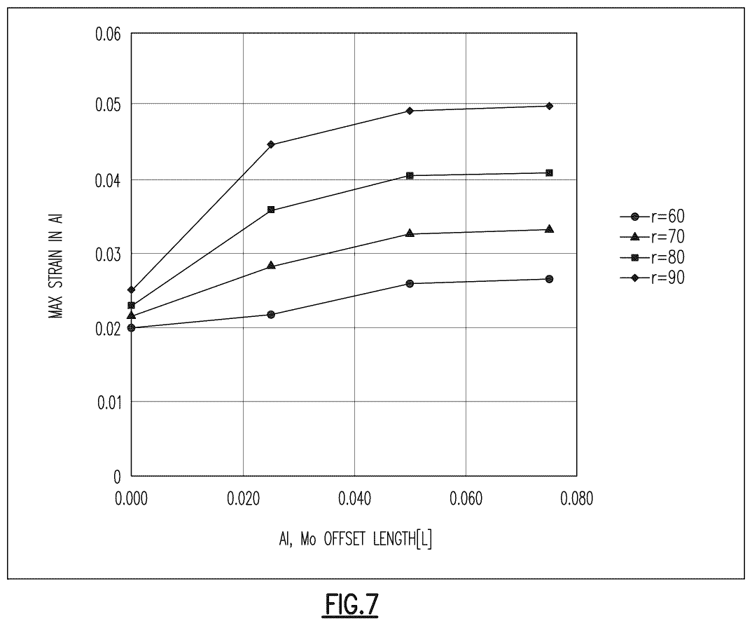

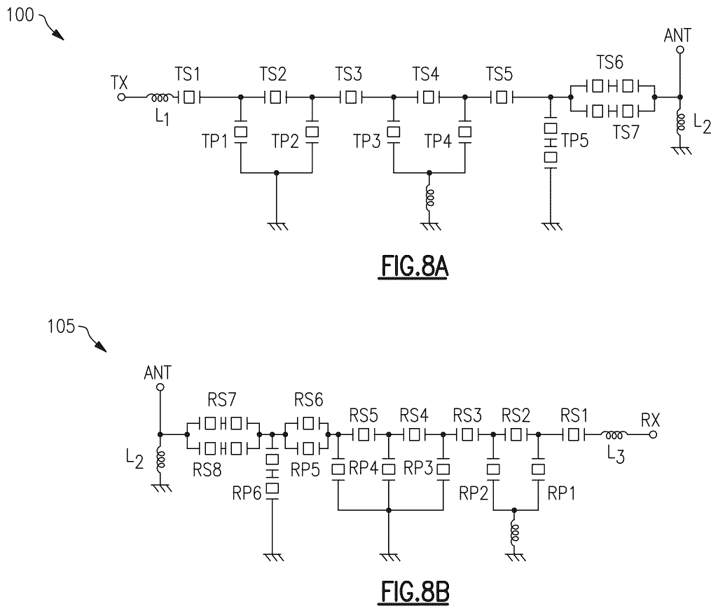

The transition structure 50 and the passivation layer 54 can contribute to reducing stress or strain in the IDT electrode 12′, thereby improving nonlinearity of the SAW device 5. The strain in the IDT electrode (e.g., in the second layer 16) can be further minimized by shaping the second layer 16 to have a sidewall with a tapered angle of less than 90 degrees, or by providing a width difference between the widths of the first and second layers 14, 16 of the IDT electrode 12. Such strain reducing structures are described with respect to FIGS. 6A-7B. FIGS. 6A-6C only illustrate dual layer IDT electrodes. However, any suitable principles and advantages disclosed herein related to IDT electrodes can be combined with the shapes of the first and second layers 14, 16 shown in FIGS. 6A-6C. For example, the third layer 17 or the transition structure 50 can be provided between the first and second layers 14, 16 shown in FIGS. 6A-6C.

FIGS. 6A-6C are schematic cross-sectional side views of SAW devices 6a, 6b, 6c showing simulated strain distributions in the SAW devices 6a, 6b, 6c with different sidewall angles of the second layer 16 (e.g., the aluminum layer). In the simulation of FIG. 6A, an angle r1 between a sidewall 16a and a bottom side 16b of the second layer 16 is set to 90 degrees. The bottom side 16b can be in contact with the first layer 14 in some embodiments. In the simulation of FIG. 6B, an angle r2 between the sidewall 16a and the bottom side 16b of the second layer 16 is set to less than 90 degrees. In the simulation of FIG. 6B, an angle r3 between the sidewall 16a and the bottom side 16b of the second layer 16 is set to less than r2. FIG. 6D is a graph showing simulated maximum strain values in the second layer 16 (e.g., the aluminum layer) at different sidewall angles. FIGS. 6A-6D indicate that when the angle between the sidewall 16a and the bottom side 16b of the second layer 16 is smaller, the maximum strain in the second layer 16 can be reduced.

In some embodiments, an angle between the sidewall 16a and the bottom side 16b can be smaller than 90 degrees such that a top side 16c of the second layer 16 has a width that is less than a width of the bottom side 16b. For example, the angle between the sidewall 16a and the bottom side 16b can be in a range between 45 degrees and 95 degrees, 50 degrees and 90 degrees, or 60 degrees and 80 degrees. The first layer 14 has a sidewall 14a that extends between a bottom side 14b and a top side 14c. In some embodiments, the first layer 14 may also have an angle less than 90 degrees between the sidewall 14a and the bottom side 14b.

As shown in FIGS. 6A-6C, there can be a width difference between the widths of the first layer 14 and the second layer 16. In some embodiments, the top side 14c of the first layer 14 can have a width that is greater than the bottom side 16b of the second layer 16 such that the sidewall 16a is offset by a gap g from the sidewall 14a at the top side 14c of the first layer 14. A dimension of the gap g can be referred to as an offset length.

FIG. 7 is a graph showing simulated maximum strain values in the second layer 16 (e.g., the aluminum layer) at different sidewall angles and offset lengths. FIG. 7 indicates that when there is the gap g between the sidewalls 14a, 16a, the maximum strain in the second layer 16 can be reduced. In some embodiments, the offset length of the gap g can be in a range between 0.01 L and 0.08 L, 0.01 L and 0.06 L, 0.02 L and 0.06 L, or 0.02 L and 0.05 L.

In some embodiments, when the third layer 17 or the transition structure 50 is provided between the first and second layers 14, 16, a width of the third layer 17 or the transition structure 50 can be greater than the width of the second layer 16 and less than the width of the first layer 14.

A SAW device (e.g., an MPS SAW resonator) including any suitable combination of features disclosed herein be included in a filter arranged to filter a radio frequency signal in a fifth generation (5G) New Radio (NR) operating band within Frequency Range 1 (FR1). A filter arranged to filter a radio frequency signal in a 5G NR operating band can include one or more MPS SAW resonators disclosed herein. FR1 can be from 410 MHz to 7.125 GHZ, for example, as specified in a current 5G NR specification. In 5G applications, the thermal dissipation of the MPS SAW resonators disclosed herein can be advantageous. For example, such thermal dissipation can be desirable in 5G applications with a higher time-division duplexing (TDD) duty cycle compared to fourth generation (4G) Long Term Evolution (LTE). One or more MPS SAW resonators in accordance with any suitable principles and advantages disclosed herein can be included in a filter arranged to filter a radio frequency signal in a 4G LTE operating band and/or in a filter having a passband that includes a 4G LTE operating band and a 5G NR operating band.

FIG. 8A is a schematic diagram of an example transmit filter 100 that includes surface acoustic wave resonators according to an embodiment. The transmit filter 100 can be a band pass filter. The illustrated transmit filter 100 is arranged to filter a radio frequency signal received at a transmit port TX and provide a filtered output signal to an antenna port ANT. Some or all of the SAW resonators TS1 to TS7 and/or TP1 to TP5 can be a SAW resonator in accordance with any suitable principles and advantages disclosed herein. For instance, one or more of the SAW resonators of the transmit filter 100 can be a surface acoustic wave device disclosed herein. Alternatively or additionally, one or more of the SAW resonators of the transmit filter 100 can be any surface acoustic wave resonator disclosed herein. Any suitable number of series SAW resonators and shunt SAW resonators can be included in a transmit filter 100.

FIG. 8B is a schematic diagram of a receive filter 105 that includes surface acoustic wave resonators according to an embodiment. The receive filter 105 can be a band pass filter. The illustrated receive filter 105 is arranged to filter a radio frequency signal received at an antenna port ANT and provide a filtered output signal to a receive port RX. Some or all of the SAW resonators RS1 to RS8 and/or RP1 to RP6 can be SAW resonators in accordance with any suitable principles and advantages disclosed herein. For instance, one or more of the SAW resonators of the receive filter 105 can be a surface acoustic wave device disclosed herein. Alternatively or additionally, one or more of the SAW resonators of the receive filter 105 can be any surface acoustic wave resonator disclosed herein. Any suitable number of series SAW resonators and shunt SAW resonators can be included in a receive filter 105.

Although FIGS. 8A and 8B illustrate example ladder filter topologies, any suitable filter topology can include a SAW resonator in accordance with any suitable principles and advantages disclosed herein. Example filter topologies include ladder topology, a lattice topology, a hybrid ladder and lattice topology, a multi-mode SAW filter, a multi-mode SAW filter combined with one or more other SAW resonators, and the like.

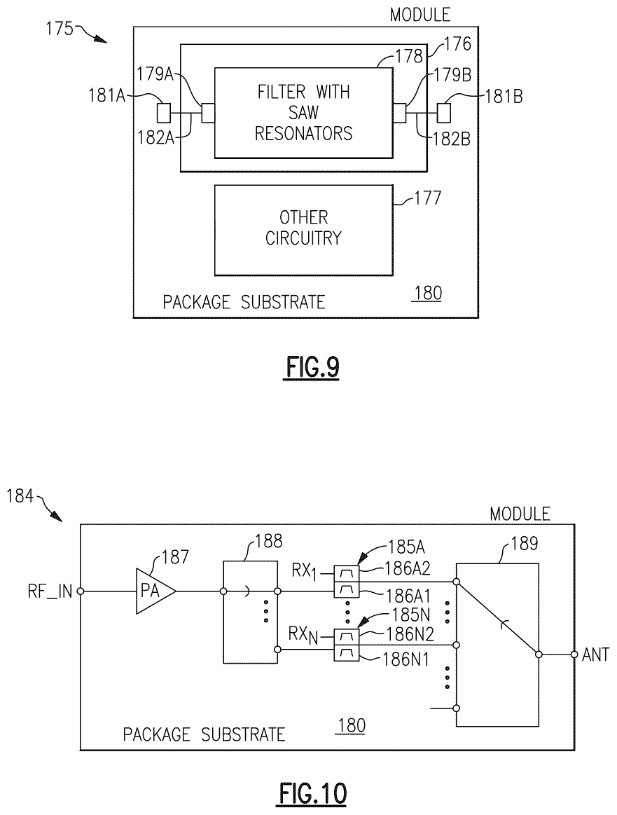

FIG. 9 is a schematic diagram of a radio frequency module 175 that includes a surface acoustic wave component 176 according to an embodiment. The illustrated radio frequency module 175 includes the SAW component 176 and other circuitry 177. The SAW component 176 can include one or more SAW resonators with any suitable combination of features of the SAW resonators disclosed herein. The SAW component 176 can include a SAW die that includes SAW resonators.

The SAW component 176 shown in FIG. 9 includes a filter 178 and terminals 179A and 179B. The filter 178 includes SAW resonators. One or more of the SAW resonators can be implemented in accordance with any suitable principles and advantages of any surface acoustic wave device disclosed herein. The terminals 179A and 178B can serve, for example, as an input contact and an output contact. The SAW component 176 and the other circuitry 177 are on a common packaging substrate 180 in FIG. 9. The package substrate 180 can be a laminate substrate. The terminals 179A and 179B can be electrically connected to contacts 181A and 181B, respectively, on the packaging substrate 180 by way of electrical connectors 182A and 182B, respectively. The electrical connectors 182A and 182B can be bumps or wire bonds, for example. The other circuitry 177 can include any suitable additional circuitry. For example, the other circuitry can include one or more one or more power amplifiers, one or more radio frequency switches, one or more additional filters, one or more low noise amplifiers, the like, or any suitable combination thereof. The radio frequency module 175 can include one or more packaging structures to, for example, provide protection and/or facilitate easier handling of the radio frequency module 175. Such a packaging structure can include an overmold structure formed over the packaging substrate 180. The overmold structure can encapsulate some or all of the components of the radio frequency module 175.

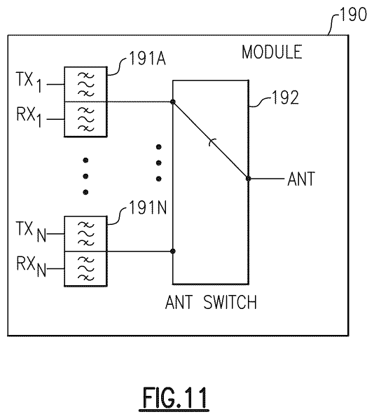

FIG. 10 is a schematic diagram of a radio frequency module 184 that includes a surface acoustic wave resonator according to an embodiment. As illustrated, the radio frequency module 184 includes duplexers 185A to 185N that include respective transmit filters 186A1 to 186N1 and respective receive filters 186A2 to 186N2, a power amplifier 187, a select switch 188, and an antenna switch 189. In some instances, the module 184 can include one or more low noise amplifiers configured to receive a signal from one or more receive filters of the receive filters 186A2 to 186N2. The radio frequency module 184 can include a package that encloses the illustrated elements. The illustrated elements can be disposed on a common packaging substrate 180. The packaging substrate can be a laminate substrate, for example.

The duplexers 185A to 185N can each include two acoustic wave filters coupled to a common node. The two acoustic wave filters can be a transmit filter and a receive filter. As illustrated, the transmit filter and the receive filter can each be band pass filters arranged to filter a radio frequency signal. One or more of the transmit filters 186A1 to 186N1 can include one or more SAW resonators in accordance with any suitable principles and advantages disclosed herein. Similarly, one or more of the receive filters 186A2 to 186N2 can include one or more SAW resonators in accordance with any suitable principles and advantages disclosed herein. Although FIG. 10 illustrates duplexers, any suitable principles and advantages disclosed herein can be implemented in other multiplexers (e.g., quadplexers, hexaplexers, octoplexers, etc.) and/or in switch-plexers and/or to standalone filters.

The power amplifier 187 can amplify a radio frequency signal. The illustrated switch 188 is a multi-throw radio frequency switch. The switch 188 can electrically couple an output of the power amplifier 187 to a selected transmit filter of the transmit filters 186A1 to 186N1. In some instances, the switch 188 can electrically connect the output of the power amplifier 187 to more than one of the transmit filters 186A1 to 186N1. The antenna switch 189 can selectively couple a signal from one or more of the duplexers 185A to 185N to an antenna port ANT. The duplexers 185A to 185N can be associated with different frequency bands and/or different modes of operation (e.g., different power modes, different signaling modes, etc.).

FIG. 11 is a schematic block diagram of a module 190 that includes duplexers 191A to 191N and an antenna switch 192. One or more filters of the duplexers 191A to 191N can include any suitable number of surface acoustic wave resonators in accordance with any suitable principles and advantages discussed herein. Any suitable number of duplexers 191A to 191N can be implemented. The antenna switch 192 can have a number of throws corresponding to the number of duplexers 191A to 191N. The antenna switch 192 can electrically couple a selected duplexer to an antenna port of the module 190.

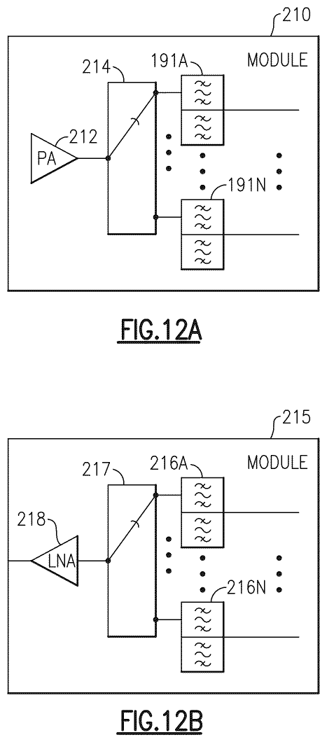

FIG. 12A is a schematic block diagram of a module 210 that includes a power amplifier 212, a radio frequency switch 214, and duplexers 191A to 191N in accordance with one or more embodiments. The power amplifier 212 can amplify a radio frequency signal. The radio frequency switch 214 can be a multi-throw radio frequency switch. The radio frequency switch 214 can electrically couple an output of the power amplifier 212 to a selected transmit filter of the duplexers 191A to 191N. One or more filters of the duplexers 191A to 191N can include any suitable number of surface acoustic wave resonators in accordance with any suitable principles and advantages discussed herein. Any suitable number of duplexers 191A to 191N can be implemented.

FIG. 12B is a schematic block diagram of a module 215 that includes filters 216A to 216N, a radio frequency switch 217, and a low noise amplifier 218 according to an embodiment. One or more filters of the filters 216A to 216N can include any suitable number of acoustic wave resonators in accordance with any suitable principles and advantages disclosed herein. Any suitable number of filters 216A to 216N can be implemented. The illustrated filters 216A to 216N are receive filters. In some embodiments, one or more of the filters 216A to 216N can be included in a multiplexer that also includes a transmit filter. The radio frequency switch 217 can be a multi-throw radio frequency switch. The radio frequency switch 217 can electrically couple an output of a selected filter of filters 216A to 216N to the low noise amplifier 218. In some embodiments, a plurality of low noise amplifiers can be implemented. The module 215 can include diversity receive features in certain applications.

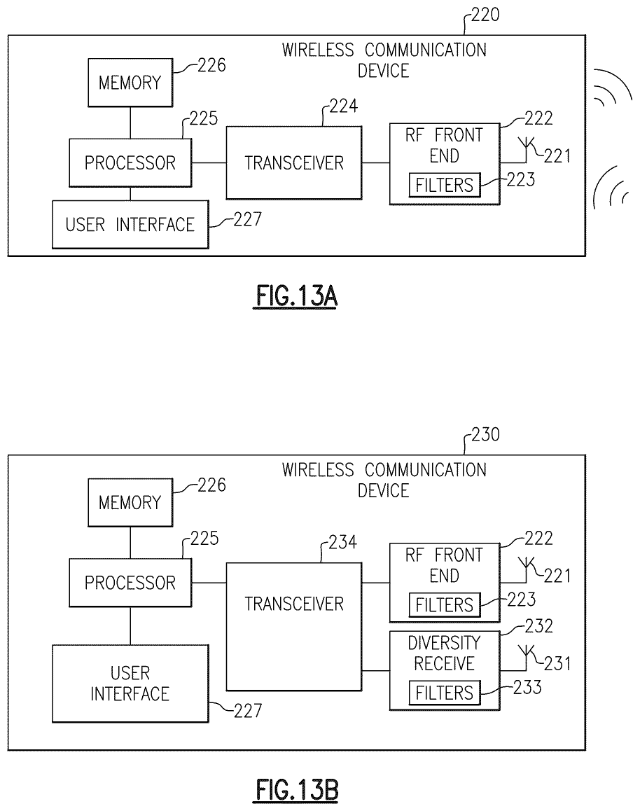

FIG. 13A is a schematic diagram of a wireless communication device 220 that includes filters 223 in a radio frequency front end 222 according to an embodiment. The filters 223 can include one or more SAW resonators in accordance with any suitable principles and advantages discussed herein. The wireless communication device 220 can be any suitable wireless communication device. For instance, a wireless communication device 220 can be a mobile phone, such as a smart phone. As illustrated, the wireless communication device 220 includes an antenna 221, an RF front end 222, a transceiver 224, a processor 225, a memory 226, and a user interface 227. The antenna 221 can transmit/receive RF signals provided by the RF front end 222. Such RF signals can include carrier aggregation signals. Although not illustrated, the wireless communication device 220 can include a microphone and a speaker in certain applications.

The RF front end 222 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 222 can transmit and receive RF signals associated with any suitable communication standards. The filters 223 can include SAW resonators of a SAW component that includes any suitable combination of features discussed with reference to any embodiments discussed above.

The transceiver 224 can provide RF signals to the RF front end 222 for amplification and/or other processing. The transceiver 224 can also process an RF signal provided by a low noise amplifier of the RF front end 222. The transceiver 224 is in communication with the processor 225. The processor 225 can be a baseband processor. The processor 225 can provide any suitable base band processing functions for the wireless communication device 220. The memory 226 can be accessed by the processor 225. The memory 226 can store any suitable data for the wireless communication device 220. The user interface 227 can be any suitable user interface, such as a display with touch screen capabilities.

FIG. 13B is a schematic diagram of a wireless communication device 230 that includes filters 223 in a radio frequency front end 222 and a second filter 233 in a diversity receive module 232. The wireless communication device 230 is like the wireless communication device 200 of FIG. 13A, except that the wireless communication device 230 also includes diversity receive features. As illustrated in FIG. 13B, the wireless communication device 230 includes a diversity antenna 231, a diversity module 232 configured to process signals received by the diversity antenna 231 and including filters 233, and a transceiver 234 in communication with both the radio frequency front end 222 and the diversity receive module 232. The filters 233 can include one or more SAW resonators that include any suitable combination of features discussed with reference to any embodiments discussed above.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHz. Acoustic wave resonators and/or filters disclosed herein can filter RF signals at frequencies up to and including millimeter wave frequencies.

Aspects of this disclosure can be implemented in various electronic devices. Examples of the electronic devices can include, but are not limited to, consumer electronic products, parts of the consumer electronic products such as packaged radio frequency modules and/or packaged filter components, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. As used herein, the term “approximately” intends that the modified characteristic need not be absolute, but is close enough so as to achieve the advantages of the characteristic. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A surface acoustic wave device comprising:
a piezoelectric layer; and
a multi-layer interdigital transducer electrode in electrical communication with the piezoelectric layer, the multi-layer interdigital transducer electrode including a first layer, a second layer, and a third layer between the first layer and the second layer, a first mass density of the first layer being greater than a second mass density of the second layer, and a third density of the third layer being greater than the second mass density.

2. The surface acoustic wave device of claim 1 wherein the first layer includes molybdenum, tungsten, platinum, or ruthenium.

3. The surface acoustic wave device of claim 1 wherein the second layer includes aluminum.

4. The surface acoustic wave device of claim 1 wherein the third layer includes titanium.

5. The surface acoustic wave device of claim 1 wherein the piezoelectric layer includes lithium tantalate or lithium niobate.

6. The surface acoustic wave device of claim 1 wherein the third layer is thinner than the first layer.

7. The surface acoustic wave device of claim 1 wherein the third layer is thinner than the second layer.

8. The surface acoustic wave device of claim 1 wherein a thickness of the second layer is in a range between 1.8 and 2.2 times a thickness of the first layer.

9. The surface acoustic wave device of claim 1 further comprising a support substrate and a functional layer between the support substrate and the piezoelectric layer.

10. The surface acoustic wave device of claim 1 wherein the second layer has a sidewall that extends between a bottom side facing the third layer and a top side opposite the bottom side, an angle between the sidewall and the bottom side is in a range between 45 degrees and 95 degrees.

11. The surface acoustic wave device of claim 10 wherein a first width of the first layer is greater than a second width of the second layer.

12. The surface acoustic wave device of claim 11 wherein the sidewall of the second layer is offset from a sidewall of the first layer by an offset length in a range between 0.01 L and 0.08 L, where L is a wavelength of L of a wave generated by the surface acoustic wave device.

13. The surface acoustic wave device of claim 1 wherein the multi-layer interdigital transducer electrode further includes a fourth layer between the first layer and the third layer.

14. The surface acoustic wave device of claim 13 wherein the multi-layer interdigital transducer electrode further includes a fifth layer between the third layer and the fourth layer, the fourth layer includes the same material as the second layer.

15. The surface acoustic wave device of claim 1 further comprising a passivation layer over the multi-layer interdigital transducer electrode.

16. A surface acoustic wave device comprising:
a piezoelectric layer; and
a multi-layer interdigital transducer electrode in electrical communication with the piezoelectric layer, the multi-layer interdigital transducer electrode including a first layer, a second layer, and a third layer between the first layer and the second layer, the second layer being more flexible than the first and second layers, and the third layer being more flexible than the first layer.

17. The surface acoustic wave device of claim 16 wherein the first layer includes molybdenum, tungsten, platinum, or ruthenium.

18. The surface acoustic wave device of claim 16 wherein the second layer includes aluminum and the third layer includes titanium.

19. A surface acoustic wave device comprising:
a piezoelectric layer; and
a multi-layer interdigital transducer electrode in electrical communication with the piezoelectric layer, the multi-layer interdigital transducer electrode including a first layer, a second layer, and a third layer between the first layer and the second layer, the second layer includes aluminum, and the third layer includes titanium.

20. The surface acoustic wave device of claim 19 wherein the third layer being thinner than the first layer and the second layer.
